(19) United States
(12) Patent Application Publication
(10) Pub. No.: US 2008/0054984 A1
(43) Pub. Date: Mar. 6, 2008

(54) HIGH VOLTAGE GATE DRIVER IC WITH RAMP DRIVER

(75) Inventor: Dong Young Lee, Torrance, CA (US)

Correspondence Address: OSTROLENK FABER GERB & SOFFEN, 1180 AVENUE OF THE AMERICAS, NEW YORK, NY, 100368403, US

(73) Assignee: INTERNATIONAL RECTIFIER CORPORATION, El Segundo, CA (US)

(21) Appl. No.: 11/780,897

(22) Filed: Jul. 20, 2007

Related U.S. Application Data
(60) Provisional application No. 60/824,183, filed on Aug. 31, 2006.

(51) Int. Cl. H03K 17/56; G05F 3/16

(52) U.S. Cl. 327/419; 323/313

(57) ABSTRACT

A High Voltage Gate Driver IC (HVIC) having an internal ramp drive function for controlling a high power switch to produce ramp output voltage waveforms. The HVIC including a sensor for sensing a voltage across the power switch; a reference generator for generating a reference voltage signal in accordance with an external setting; and a feedback circuit to provide a feedback gain to control a gate of the power switch, the feedback circuit making voltage across the power switch follow to reference and stable, wherein the HVIC generates the ramp drive function with minimized circuit components external to the HVIC.

### CROSS-REFERENCE TO RELATED APPLICATION

This application is based on and claims priority to U.S. Provisional Patent Application Ser. No. 60/824,183, filed on Aug. 31, 2006 and entitled HIGH VOLTAGE GATE DRIVER IC (HVIC) WITH RAMP DRIVER, the entire disclosure of which is hereby incorporated by reference.

### BACKGROUND OF THE INVENTION

The present invention relates to a High Voltage Gate Driver IC (HVIC), and more particularly to driving a power switch to implement a ramp output voltage waveform in the HVIC in a Plasma Display Panel (PDP) gate driver IC.

PDP systems require a special output voltage waveform to reset the PDP. Such special output voltage waveforms have slow dV/dt characteristic, which is usually of a magnitude of several V/us. FIG. 1 illustrates a schematic of a conventional PDP ramp driver 10 with a general gate driver IC 12. The ramp driver 10 requires an auxiliary circuit 14 to make a switch 16 turn-ON slowly. As illustrated in graph 18, a ramp provided by the driver 10 is over a period of 100 to 300 us and for a voltage V_{SET} of 200 to 300V.

FIG. 2 illustrates a ramp driver circuit 20 that is used in a functioning system. A voltage Vcbtsp of the circuit 20 is varied by bootstrap conditions of the functioning system. In addition, the slope of dVds/dt varies according to temperature because the temperature characteristic of passive components and the switch may vary widely. To make the output voltage of the driver 12 constant and operation stable, the driver circuit 20 requires additional components. It includes a Zener diode D_{Z} and a variable resistor R_{VAR} that functions to control the slope of dVds/dt

Further, the switch 16 includes a high-voltage capacitor C_{RAMP} coupled to its gate and drain terminals and the gate driver 12. The capacitor C_{RAMP} has two functions. The first is to enlarge gate-drain capacitance of the switch 16. The second function is to make the waveform stable through a feedback of Vds.

As in circuit 10 of FIG. 1, the gate driver 12 includes a switching stage of two switches Q1 and Q2 connected at a switching node A and in parallel to a bootstrap capacitor C_{BTSP}. The two switches Q1 and Q2 are driven by an amplifier receiving a square input signal, with the switch Q1 receiving the inverse of the signal. Like the auxiliary circuit 14, circuit 20 includes the variable resistor R_{VAR} connected between the switching node A and the gate of the switch 16 and the Zener diode D_{Z} connected in parallel with the switch Q2.

### SUMMARY OF THE INVENTION

It is an object of the present invention to provide an HVIC having an internal ramp drive function so as to eliminate an external auxiliary ramp generating circuit, thus saving system cost and space.

It is an object of the present invention to provide a stable HVIC output enabled by an internal sensing and feedback function.

It is another object of the present invention to reduce external auxiliary circuits of the HVIC while providing a stable output waveform regardless of outside disturbances.

Provided is a High Voltage Gate Driver IC (HVIC) having an internal ramp drive function for controlling a high power switch to produce ramp output voltage waveforms. The HVIC includes a sensor for sensing a voltage across the power switch; a reference generator for generating a reference voltage signal in accordance with an external setting; and a feedback circuit to provide a feedback gain to control a gate of the power switch, the feedback circuit making voltage across the power switch follow to reference and stable, wherein the HVIC generates the ramp drive function with minimized circuit components external to the HVIC.

Other features and advantages of the present invention will become apparent from the following description of the invention that refers to the accompanying drawings.

### BRIEF DESCRIPTION OF THE DRAWINGS

FIG. 1 is a diagram of a conventional HVIC using external ramp generating circuits for driving the power switch;

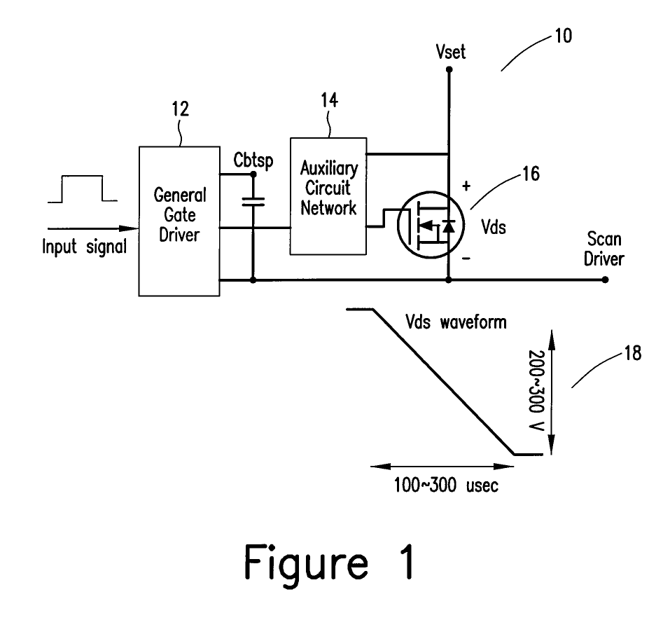

FIG. 2 is a diagram of application of the HVIC of FIG. 1 in a conventional PDP ramp driver including additional external ramp generating circuitry required for smooth operations in a functioning system;

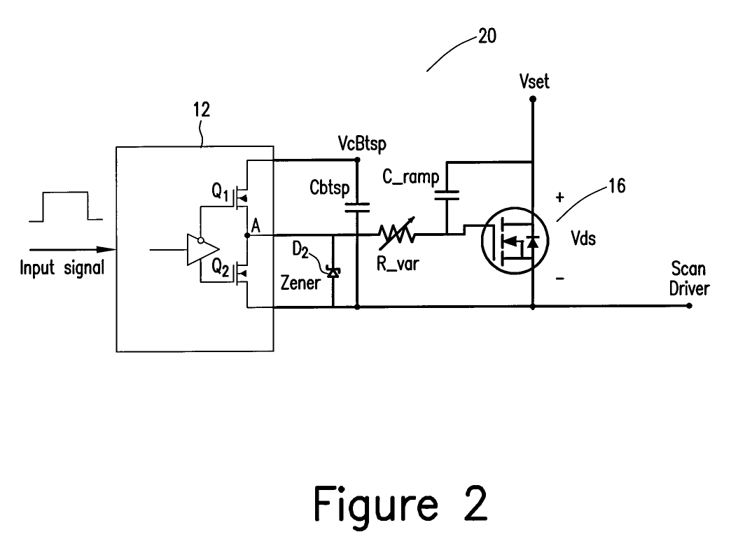

FIG. 3 is a diagram of an HVIC of an embodiment of the present invention; and

FIG. 4 is a diagram of an exemplary application of the HVIC of FIG. 1 in a PDP ramp driver using an internal ramp drive function.

### DETAILED DESCRIPTION OF EMBODIMENTS OF THE INVENTION

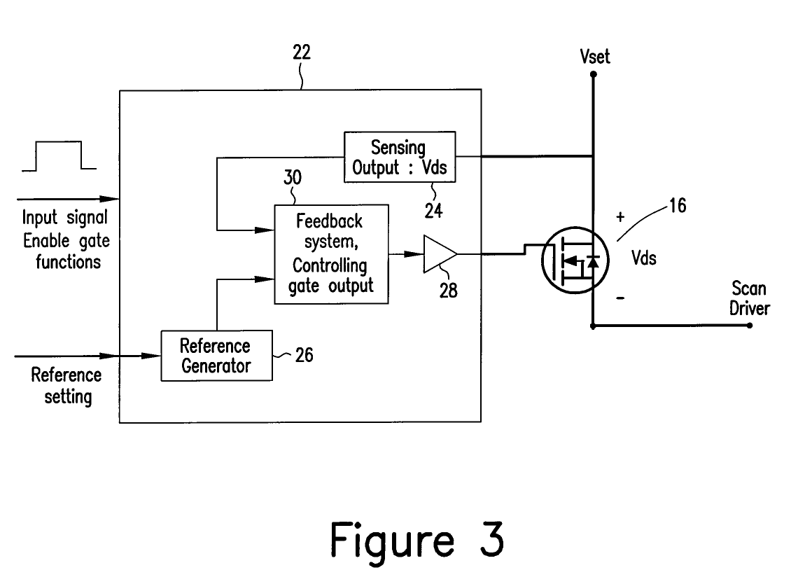

The present invention provides an HVIC having a stable ramp driver function for the power switch 16 using internal sensing and feedback function of the HVIC with minimized external circuits. The inventive HVIC circuit 22 having an internal ramp driver function is illustrated in FIG. 3. The HVIC circuit 22 includes a sensing circuit 24 that senses output voltage Vds; a reference generator 26 to generate a reference signal from external reference settings; a feedback logic system 30 and an output buffer 28 to control the gate of the switch 16. The HVIC circuit 22 provides a stable ramp waveform. Through the use of the fast feedback system 30, the HVIC circuit 22 can provide a stable ramp output regardless of disturbances.

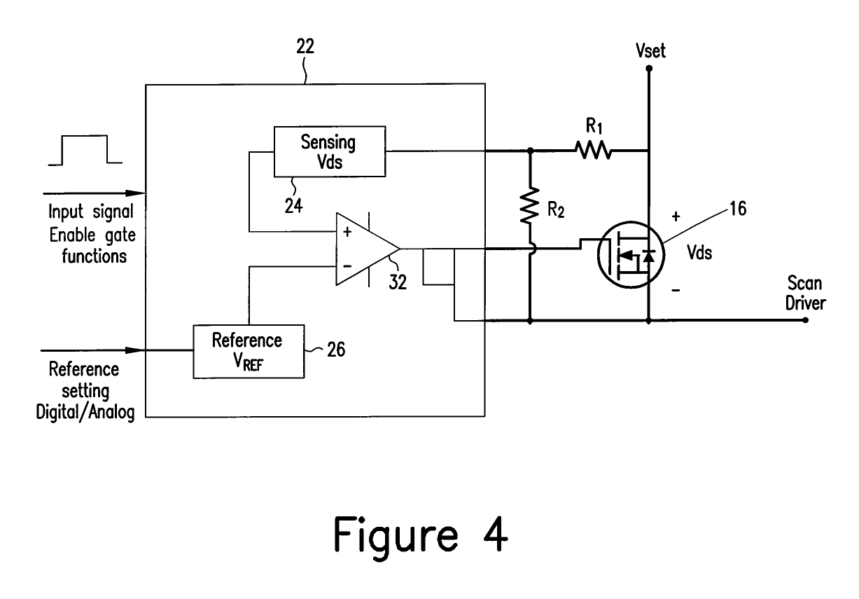

One exemplary embodiment of the HVIC circuit 22 of the present invention that provides an internal ramp driver function is illustrated in FIG. 4. As shown, the HVIC circuit 22 further includes external resistors R₁ and R₂ that are parallel connected to the power switch 16. The sensing circuit 24 senses divided output voltage changes over switch. This is achieved by measuring a voltage signal Vds at a node between R₁ and R₂.

Further, the HVIC circuit 22 includes an operational error amplifier 32 that receives the voltage signal Vds at its positive terminal and a reference constant voltage signal V_{REF} at its negative terminal. The reference constant voltage signal V_{REF} is generated by the reference generator circuit 26 from an externally set reference. The output of the operational error amplifier 32 provides a feedback gain for controlling the gate of the switch 16.

Thus, the HVIC circuit 22 provides stable ramp output while eliminating external auxiliary circuits. Therefore, application of the HVIC circuit 22 in PDP reset ramp drivers can save system cost and space and improve performance.

Although the present invention has been described in relation to particular embodiments thereof, many other variations and modifications and other uses will become apparent to those skilled in the art. It is preferred, therefore, that the present invention not be limited by the specific disclosure herein.

What is claimed is:

1. A High Voltage Gate Driver IC (HVIC) having an internal ramp drive function for controlling a high power switch to produce ramp output voltage waveforms, the HVIC comprising:
a sensor for sensing a voltage across the power switch;
a reference generator for generating a reference current signal in accordance with an external setting; and
a feedback circuit to provide a feedback gain to control a gate of the power switch, the feedback circuit making voltage across the power switch follow to reference and stable, wherein the HVIC generates the ramp drive function with minimized circuit components external to the HVIC.

2. The HVIC of claim 1, further comprising a pair of resistors parallel coupled to the high power switch, and wherein the voltage comprises a first divided output voltage changes over switch, the first voltage signal being monitored at a node coupled to the high power switch and the pair of resistors.

3. The HVIC of claim 2, wherein the feedback system comprises an operational error amplifier that receives the first voltage signal at its positive terminal and the reference voltage signal at its negative terminal and produces a stable ramp output.

4. The HVIC of claim 3, wherein the stable ramp output is produced regardless of disturbances.

5. The HVIC of claim 4, wherein the power switch is controlled to implement the ramp output voltage waveforms to allow slow and stepwise turn-ON of the high power switch.

6. The HVIC of claim 5, wherein the ramp output voltage waveforms have a slow and stepwise dV/dt characteristic of several V/us.

7. The HVIC of claim 6, wherein the HVIC is used for resetting Plasma Display Panels (PDP).

8. The HVIC of claim 1, wherein the HVIC is provided on the same integrated circuit with the high power switch.
